(19) United States
(12) Patent Application Publication
(10) Pub. No.: US 2009/0011120 A1
(43) Pub. Date: Jan. 8, 2009

(54) Plasma Treating Apparatus, Electrode Member for Plasma Treating Apparatus, Electrode Member Manufacturing Method and Recycling Method

(75) Inventor: Tetsuhiro Iwai, Fukuoka (JP)

Correspondence Address: PEARNE & GORDON LLP, 1801 EAST 9TH STREET, SUITE 1200, CLEVELAND, OH, 44114-3108, US

(73) Assignee: Matsushita Electric Industrial Co., Ltd, Osaka (JP)

(21) Appl. No.: 11/816,110

(22) PCT Filed: Sep. 7, 2006
(86) PCT No.: PCT/JP2006/318226

§ 371 Date: Aug. 13, 2007

(30) Foreign Application Priority Data
Sep. 12, 2005 (JP) 2005-263410

(51) Int. Cl. B05D 5/12; C23F 1/08; C23C 16/00

(52) U.S. Cl. 427/58; 156/345.47; 118/723 E

(57) ABSTRACT

In a plasma treating apparatus for carrying out a plasma treatment by setting a plate-shaped work to be an object, an electrode member 46 to abut on a lower surface of the work is constituted by soldering a plate-shaped suction member 45 having a plurality of through holes 45a formed thereon and a cooling plate 44, and a sprayed film 65 obtained by spraying alumina is formed on an upper surface of the suction member 45, and furthermore, an edge of a hole portion 45d in which the through holes 45a are formed is covered with the sprayed film 65. Consequently, it is possible to reduce a consumption of the electrode member due to sputtering to prolong a lifetime, thereby decreasing a component consuming cost and preventing an inner part of the apparatus from being contaminated by a scattered substance.

### TECHNICAL FIELD

The present invention relates to a plasma treating apparatus for carrying out a plasma treatment by setting a plate-shaped work such as a semiconductor wafer to be an object, an electrode member for the plasma treating apparatus, a method of manufacturing the electrode member, and a recycling method.

### BACKGROUND ART

A semiconductor apparatus to be mounted on a substrate of an electronic apparatus is manufactured by cutting, into individual pieces, a semiconductor element subjected to a circuit pattern formation in a wafer state. In recent years, a thickness of the semiconductor element has been reduced so that the difficulty of handling of the semiconductor element in the wafer state has been increased. Consequently, there has been used plasma dicing for carrying out dicing to cut and divide a semiconductor wafer into the semiconductor elements to be the individual pieces through plasma etching (for example, see Patent Document 1).

In the plasma dicing, the plasma etching is carried out in a state in which portions other than a dicing line are subjected to masking by a resist film, thereby cutting the semiconductor wafer along the dicing line. After the dicing, it is necessary to remove the resist film. In the example of the prior art disclosed in the Patent Document 1, therefore, the resist film is removed by plasma ashing using the same plasma treating apparatus.

In the plasma ashing, a reactive product generated in the removal of the resist film is scattered as particles and they are stuck and deposited onto an inner part of the plasma treating apparatus. For this reason, it is necessary to execute cleaning which is intended for removing these stuck and deposited substances. In the cleaning, the plasma treatment is carried out in a state in which an upper surface of a lower electrode to mount the semiconductor wafer thereon is exposed so that the stuck and deposited substances are removed.

[Patent Document 1] JP-A-2004-172364 Publication

In the conventional plasma treating apparatus described in the example of the Patent Document, however, there has been the following problem due to a structure of the lower electrode on which the wafer is to be mounted. More specifically, in the conventional apparatus, most of a surface of an electrode member to abut on the wafer has such a structure that a metallic surface is exposed in the lower electrode. Every time the cleaning is executed, therefore, the metal portion of the electrode member is exposed to plasma. For this reason, the surface of the electrode member is removed by a sputtering effect of the plasma so that a lifetime of a component of the electrode member is shortened and a component consuming cost is thus raised, and furthermore, a scattered substance generated by the sputtering is stuck to an internal surface of the apparatus, resulting in a contamination.

### DISCLOSURE OF INVENTION

Therefore, it is an object of the invention to provide a plasma treating apparatus capable of increasing a lifetime of an electrode member constituting a lower electrode to reduce a component consuming cost, and furthermore, preventing an inner part of the apparatus from being contaminated by the sticking of a scattered substance, an electrode member for the plasma treating apparatus, a method of manufacturing the electrode member, and a recycling method.

The invention provides a plasma treating apparatus for carrying out a plasma treatment by setting a plate-shaped work to be an object, comprising a vacuum chamber, a lower electrode provided in the vacuum chamber and having the work mounted thereon, an upper electrode disposed above the lower electrode, a processing space formed between the lower electrode and the upper electrode, and plasma generating means for generating a plasma in the processing space, wherein an electrode member to abut on a lower surface of the work in the lower electrode includes a plate-shaped member on which a plurality of through holes is formed, and a dielectric film formed by spraying a dielectric onto an upper surface of the plate-shaped member and taking such a shape as to cover an edge of a hole portion in which the through holes are formed on the upper surface of the plate-shaped member.

The invention provides an electrode member for a plasma treating apparatus for carrying out a plasma treatment by setting a plate-shaped work to be an object which is used in the plasma treating apparatus and abuts on a lower surface of the work in a lower electrode having the work mounted thereon, comprising a plate-shaped member on which a plurality of through holes is formed, and a dielectric film formed by spraying a dielectric onto an upper surface of the plate-shaped member and taking such a shape as to cover an edge of a hole portion in which the through holes are formed on the upper surface of the plate-shaped member.

The invention provides an electrode member manufacturing method of manufacturing an electrode member for a plasma treating apparatus for carrying out a plasma treatment by setting a plate-shaped work to be an object which is used in the plasma treating apparatus and abuts on a lower surface of the work in a lower electrode having the work mounted thereon, comprising a through hole forming step of forming a plurality of through holes on a plate-shaped member, a spraying step of spraying a dielectric onto an upper surface of the plate-shaped member having the through holes formed thereon, thereby forming a dielectric film taking such a shape as to cover an edge of a hole portion in which the through holes are formed on the upper surface of the plate-shaped member, and a surface polishing step of mechanically polishing a surface of the plate-shaped member having the dielectric film formed thereon.

The invention provides an electrode member recycling method of reusing an electrode member which is used in a plasma treating apparatus for carrying out a plasma treatment by setting a plate-shaped work to be an object and is manufactured by a manufacturing method comprising a through hole forming step of forming a plurality of through holes on a plate-shaped member, a spraying step of spraying a dielectric onto an upper surface of the plate-shaped member having the through holes formed thereon, thereby forming a dielectric film taking such a shape as to cover an edge of a hole portion in which the through holes are formed on the upper surface of the plate-shaped member, a surface polishing step of mechanically polishing a surface of the plate-shaped member having the dielectric film formed thereon, a film removing step of removing the sprayed film of the spent electrode member, and a respraying step of spraying a dielectric onto the upper surface of the plate-shaped member obtained after removing the sprayed film, thereby forming the dielectric film again.

According to the invention, the electrode member to abut on the lower surface of the work in the lower electrode has such a structure that the dielectric is sprayed onto the upper surface of the plate-shaped member having a plurality of through holes formed thereon and the dielectric film is thus formed, and furthermore, the dielectric film covers the edge of the hole portion in which the through holes are formed on the upper surface of the plate-shaped member. Consequently, it is possible to reduce a consumption caused by the sputtering of the electrode member in the cleaning, thereby increasing the lifetime of the electrode member constituting the lower electrode to reduce a component consuming cost and to prevent the inner part of the apparatus from being contaminated by a scattered substance.

### BRIEF DESCRIPTION OF DRAWINGS

FIG. 1 is a view for explaining a structure of a plasma treating apparatus according to an embodiment of the invention,

FIG. 2 is a side sectional view showing a vacuum chamber in the plasma treating apparatus according to the embodiment of the invention,

FIG. 3 is a side sectional view showing the vacuum chamber in the plasma treating apparatus according to the embodiment of the invention,

FIG. 4 is a plan view showing the vacuum chamber in the plasma treating apparatus according to the embodiment of the invention,

FIG. 5 is a partial sectional view showing the vacuum chamber in the plasma treating apparatus according to the embodiment of the invention,

FIG. 6 is a side sectional view showing a lower electrode in the plasma treating apparatus according to the embodiment of the invention,

FIG. 7 is a plan view showing a suction plate in the plasma treating apparatus according to the embodiment of the invention,

FIG. 8 is a bottom view showing the suction plate in the plasma treating apparatus according to the embodiment of the invention,

FIG. 9 is a view for explaining an operation of an upper electrode in the plasma treating apparatus according to the embodiment of the invention,

FIG. 10 is a view for explaining an operation for opening and closing the vacuum chamber in the plasma treating apparatus according to the embodiment of the invention,

FIG. 11 is a flowchart showing the steps of manufacturing an electrode member to be used in the plasma treating apparatus according to the embodiment of the invention,

FIG. 12 is a view for explaining the steps in a method of manufacturing the electrode member to be used in the plasma treating apparatus according to the embodiment of the invention, and

FIG. 13 is a view for explaining the steps in the method of manufacturing the electrode member to be used in the plasma treating apparatus according to the embodiment of the invention.

### DESCRIPTION OF THE REFERENCE NUMERALS AND SIGNS

1 plasma treating apparatus
2 vacuum chamber
2a processing space
3 lower electrode
4 upper electrode
5 semiconductor wafer
6 upper plate
7 up-down driving portion
9 door member
11 vacuum pump
13 process gas supply portion
17 high frequency power supply
40 chamber container
40a sidewall portion
40d sealing surface
40f delivery port
44 cooling plate
45 suction member
45a through hole
46 electrode member
50 holding member
51 intermediate plate
51a outer edge portion
59 hinge shaft
65 sprayed film

### BEST MODE FOR CARRYING OUT THE INVENTION

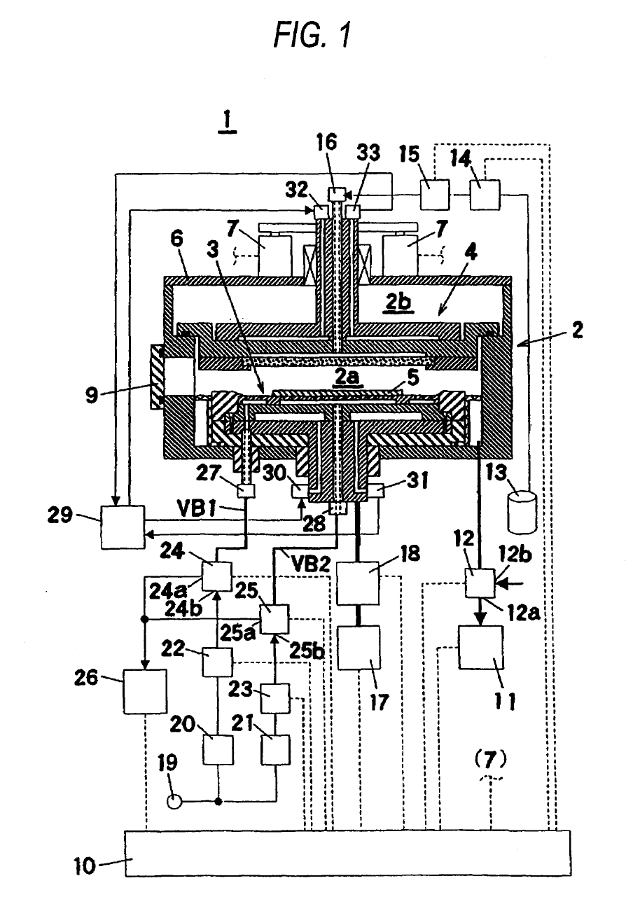

Next, an embodiment of the invention will be described with reference to the drawings. First of all, a whole structure of a plasma treating apparatus 1 will be described with reference to FIG. 1. The plasma treating apparatus 1 has the function of carrying out a plasma treatment by setting a plate-shaped work such as a semiconductor wafer to be an object. The plasma treating apparatus 1 comprises a vacuum chamber 2 for generating a plasma under a pressure reduction. A lower electrode 3 for mounting a semiconductor wafer 5 to be a work thereon is disposed in the vacuum chamber 2, and an upper electrode 4 is provided to be upward and downward movable above the lower electrode 3. The upper electrode 4 is moved upward and downward by an up-down driving portion 7 provided on an upper plate 6 to abut on an upper part of the vacuum chamber 2. In a state in which the upper electrode 4 is moved downward, a closed processing space 2a is formed between the lower electrode 3 and the upper electrode 4. In this state, a portion provided above the upper electrode 4 becomes an ordinary pressure space 2b which is isolated from the processing space 2a and in which a plasma discharge is not generated.

A delivery port for putting the work in/out which is closed by a door 9 is provided on a side surface of the vacuum chamber 2. By opening the door 9, it is possible to deliver the semiconductor wafer 5 in/out of the processing space 2a. A plasma is generated in the processing space 2a by plasma generating means which will be described below so that a plasma treatment setting, as an object, the semiconductor wafer 5 mounted on the lower electrode 3 is carried out. Herein, there are carried out plasma dicing for performing plasma etching over the semiconductor wafer 5 subjected to masking by a resist film, thereby dividing the semiconductor wafer 5 into individual pieces and plasma ashing for removing the resist film by the plasma treatment after the plasma dicing.

A switching valve 12 is connected to an internal space of the vacuum chamber 2, and a vacuum pump 11 is connected to a sucking part 12a of the switching valve 12. The vacuum pump 11 is driven in a state in which the switching valve 12 is switched into the sucking port 12a side so that an internal space of the vacuum chamber 12 is evacuated. When the switching valve 12 is switched into an air sucking port 12b side, moreover, air is introduced into the vacuum chamber 2 so that a vacuum breakdown in the processing space 2a is carried out.

A process gas supply portion 13 is connected to a joint member 16 through a flow rate control valve 14 and an opening/closing valve 15. When the process gas supply portion 13 is driven, a process gas for generating a plasma is supplied from a lower surface of the upper electrode 4 into the processing space 2a. In the case in which the plasma dicing is carried out, a fluoric gas such as SF₆ (sulfur hexafluoride) is used as a process gas. In the case in which the plasma ashing is carried out, moreover, an oxygen gas is used as the process gas. In the plasma treatment to be carried out by using the fluoric gas with the semiconductor wafer 5 to be an object, it is desirable that an interval between the upper electrode 4 and the lower electrode 3 should be set to be small in the processing space 2a in order to enhance a processing efficiency.

A high frequency power supply 17 is electrically connected to the lower electrode 3 through a matching circuit 18. When the high frequency power supply 17 is driven, a high frequency voltage is applied between the lower electrode 3 and the upper electrode 4. When the high frequency voltage is applied in a state in which the process gas is supplied after the inner part of the processing space 2a is evacuated, a plasma discharge is generated in the processing space 2a so that the process gas supplied to the processing space 2a is brought into a plasma state. Consequently, there is carried out the plasma treatment in which the semiconductor wafer 5 mounted on the lower electrode 3 is set to be the object. The matching circuit 18 serves to match impedances of a plasma discharging circuit in the processing space 2a and the high frequency power supply 17 in the generation of the plasma. In the structure, the vacuum pump 11, the process gas supply portion 13, the high frequency power supply 17 and the matching circuit 18 serve as plasma generating means for generating a plasma in the processing space 2a.

2-system independent sucking and blow lines for carrying out a vacuum suction and air blow from a through hole for a suction and blow which is provided on an upper surface are connected to the lower electrode 3. More specifically, a first sucking and blow line VB1 including a switching valve 24 is connected to a joint member 27 communicating with an outer peripheral part of the lower electrode 3, and a second sucking and blow line VB2 including a switching valve 25 is connected to a joint member 28 communicating with a central part of the lower electrode 3.

The first sucking and blow line VB1 and the second sucking and blow line VB2 have such a structure that a sucking pump 26 is connected to sucking ports 24a and 25a of the switching valves 24 and 25 respectively and an air pressure source 19 is connected to air supply ports 24b and 25b of the switching valves 24 and 25 through opening/closing valves 22 and 23 and regulators 20 and 21. By switching the switching valves 24 and 25 to the sucking port side and the air supply port side respectively, it is possible to selectively carry out a vacuum suction and an air blow from a through hole formed on an upper surface of the lower electrode 3. At this time, it is possible to set the air supplied from the air pressure source 19 to have an optional pressure by regulating the regulators 20 and 21.

The lower electrode 3 and the upper electrode 4 include cooling holes for circulating cooling water respectively, and a cooling unit 29 is connected to the cooling hole of the lower electrode 3 through joint members 30 and 31 and is connected to the cooling hole of the upper electrode 4 through joint members 32 and 33. The cooling unit 29 is driven so that a refrigerant is circulated in the cooling holes in the lower electrode 3 and the upper electrode 4. Consequently, the lower electrode 3 and the upper electrode 4 can be prevented from being overheated due to the generation of heat in a plasma treatment.

In the structure, the up-down driving portion 7, the vacuum pump 11, the switching valve 12, the flow rate control valve 14, the opening/closing valve 15, the high-frequency power supply 17, the matching circuit 18, the opening/closing valves 22 and 23, the switching valves 24 and 25, and the sucking pump 26 are controlled by a control portion 10. The control portion 10 controls the up-down driving portion 7 so that the upper electrode 4 is moved upward and downward. The control portion 10 controls the vacuum pump 11 and the switching valve 12 so that a vacuum evacuation and a vacuum breakdown in the processing space 2a are carried out.

The control portion 10 controls the flow rate control valve 14 and the switching valve 15 so that ON/OFF operations for supplying a process gas to the processing space 2a and a gas flow rate control are carried out. Moreover, the control portion 10 controls the switching valves 24 and 25 and the sucking pump 26 so that a timing for a vacuum suction from the upper surface of the lower electrode 3 is controlled. Furthermore, the control portion controls the switching valves 24 and 25 and the opening/closing valves 22 and 23 so that a timing for an air blow from the upper surface of the lower electrode 3 is controlled.

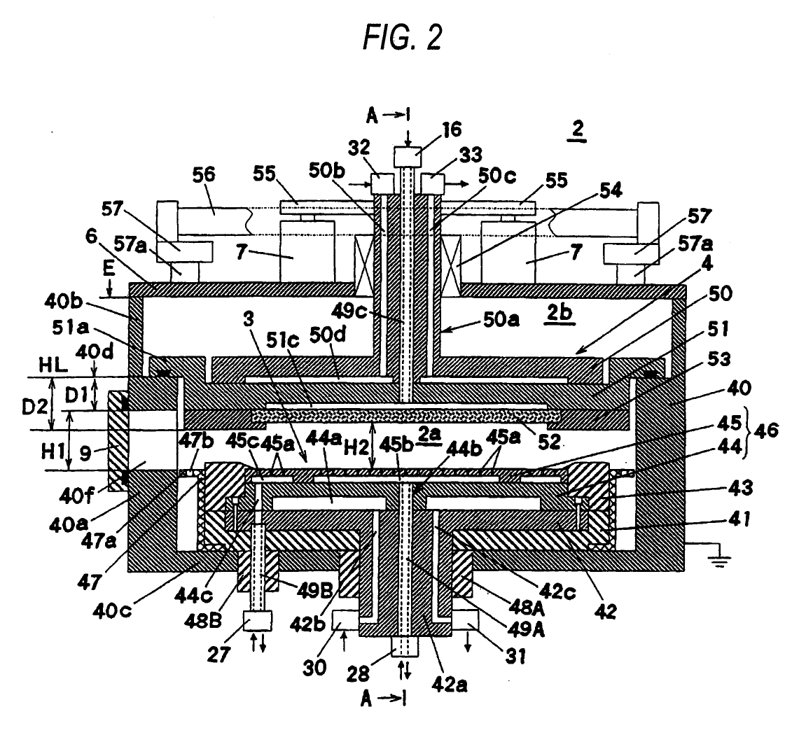

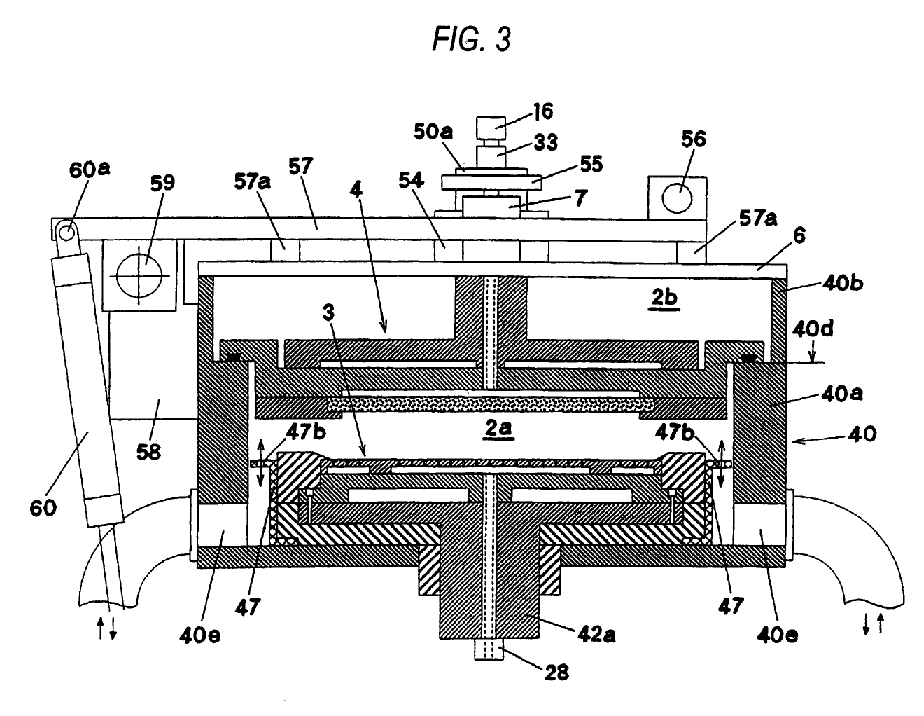

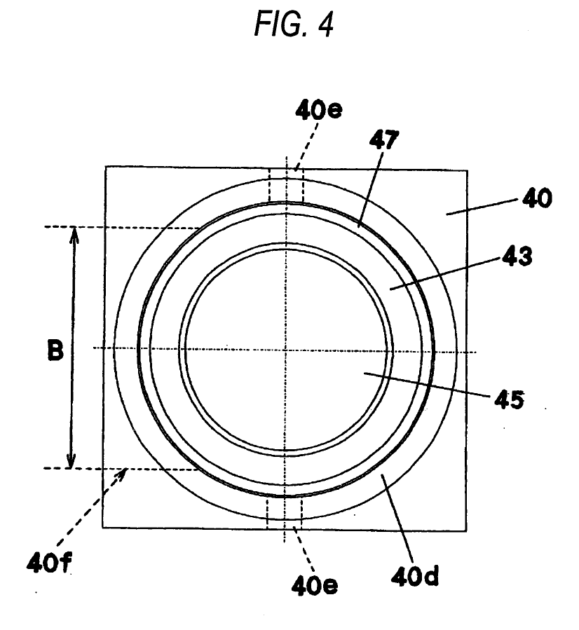

With reference to FIGS. 2, 3, 4 and 5, next, description will be given to the detailed structure of the vacuum chamber 2. FIG. 3 shows an A-A section in FIG. 2. In FIGS. 2 to 4, a chamber container 40 constituting a main body of the vacuum chamber 2 is a cylindrical container formed by circularly cutting and removing an inner part of a rectangular block taking the shape of an almost square seen on a plane (see FIG. 4), and a sidewall portion 40a connected like a ring is provided in an outer peripheral part.

As shown in FIG. 2, an upper part of the sidewall portion 40a serves as a sidewall upper portion 40b having a different sidewall thickness, and the sidewall upper portion 40b is extended upward from an intermediate height HL set below an upper end face E of the sidewall portion 40a. A ring-shaped step portion formed by a difference in the sidewall thickness between the lower part of the sidewall portion 40a and the sidewall upper portion 40b serves as a ring-shaped sealing surface 40d which is formed by an extension of the upper electrode 4 in a radial direction and on which an outer edge portion 51a abuts in a state in which the upper electrode 4 is moved downward. Herein, the sealing surface 40d has such a configuration that it is formed at the intermediate height HL positioned below the upper end face E of the sidewall portion 40a.

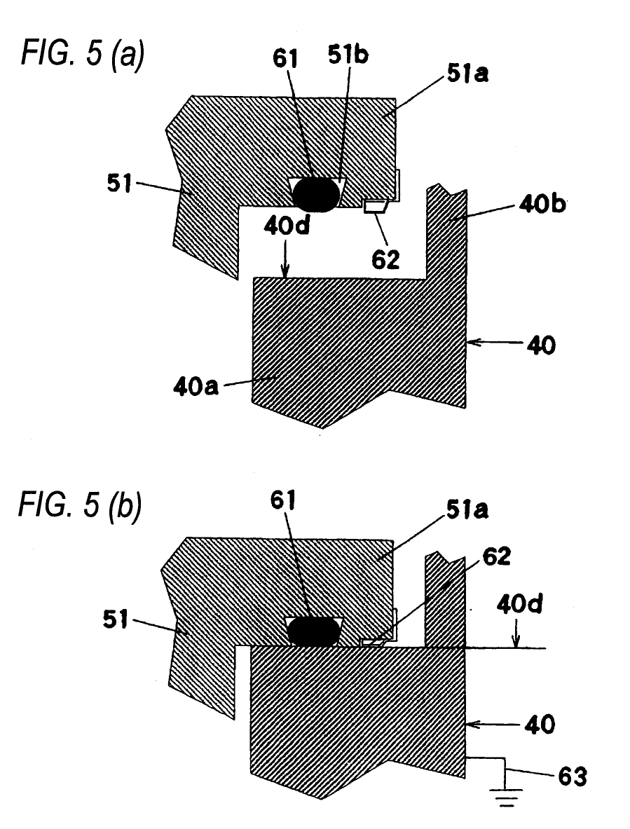

As shown in FIG. 5, a seal member 61 is attached to a seal attaching groove 51b provided on a lower surface of the outer edge portion 51a, and furthermore, a conducting fin 62 is provided on the lower surface of the outer edge portion 51a. When the upper electrode 4 is moved downward, the seal member 61 is pushed against the sealing surface 40d. Consequently, the processing space 2a is sealed against an outside. In addition, the conducting fin 62 is pushed against the sealing surface 40d. Consequently, an intermediate plate 51, that is, the upper electrode 4 is electrically conducted to the chamber container 40 grounded on a ground portion 63.

The lower electrode 3 having an upper surface on which the semiconductor wafer 5 is to be mounted is disposed in a bottom portion 40c surrounded by the sidewall portion 40a. A delivery port 40f for putting in/out a work is opened on the sidewall portion 40a in an opening height dimension H1 and an opening width dimension B (see FIG. 4) with a lower end adapted to a height level of the upper surface of the lower electrode 3. The delivery port 40f has an upper end positioned below the sealing surface 40d by a predetermined height dimension D1 in the sidewall portion 40a. More specifically, the sealing surface 40d is formed in a higher position than the delivery port 40f in the sidewall portion 40a. The door 9 for sealing the delivery port 40f is provided on an external surface of the sidewall portion 40a. When the door 9 is moved by a door opening/closing mechanism (not shown), the door 9 can be opened and closed freely.

Description will be given to the structure of the lower electrode 3. An electrode attaching portion 42 taking such a shape that a shaft portion 42a is extended downward through a dielectric 41 is held on an upper surface of the bottom portion 40c, and the shaft portion 42a penetrates through the bottom portion 40c downward through a dielectric 43. An electrode member 46 having a structure in which a cooling plate 44 and a suction member 45 are integrated with each other is attached to an upper surface of the electrode attaching portion 42 so as to be removable from the electrode attaching portion 42. The electrode member 46 is surrounded by the dielectric 43, and furthermore, a shielding member 47 fabricated by a metal such as aluminum is attached between outer peripheral surfaces of the dielectrics 41 and 43 and an inner peripheral surface of the sidewall portion 40a.

The shielding member 47 is an almost cylindrical member taking such a shape as to fit the outer peripheral surfaces of the dielectrics 41 and 43 therein. The shielding member 47 is provided with a flange portion 47a taking such a shape as to be extended in a direction of an outside diameter to block a planar clearance between the sidewall portion 40a and the dielectric 43 corresponding to a height of the upper surface of the suction member 45. The shielding member 47 has the function of shielding the clearance between the sidewall portion 40a and the dielectrics 41 and 43, thereby preventing an abnormal discharge. The flange portion 47a is provided with a ventilation hole 47b to penetrate vertically. As shown in FIG. 3, consequently, the air can be circulated between the processing space 2a on the upper surface side of the lower electrode 3 and an air supply/discharge port 40e provided in a lower part of the sidewall portion 40a in connection with the switching valve 12.

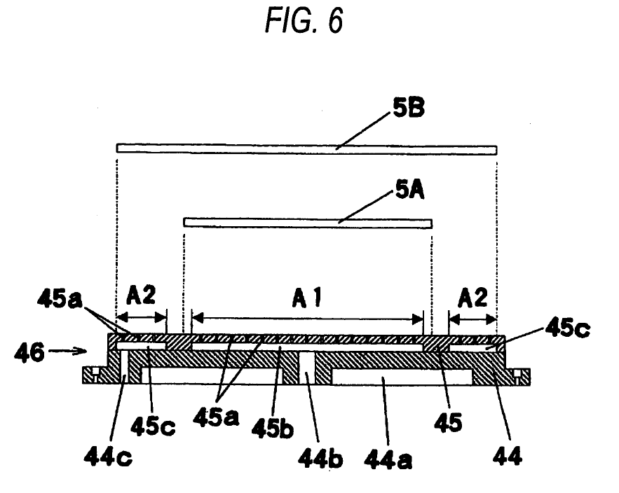

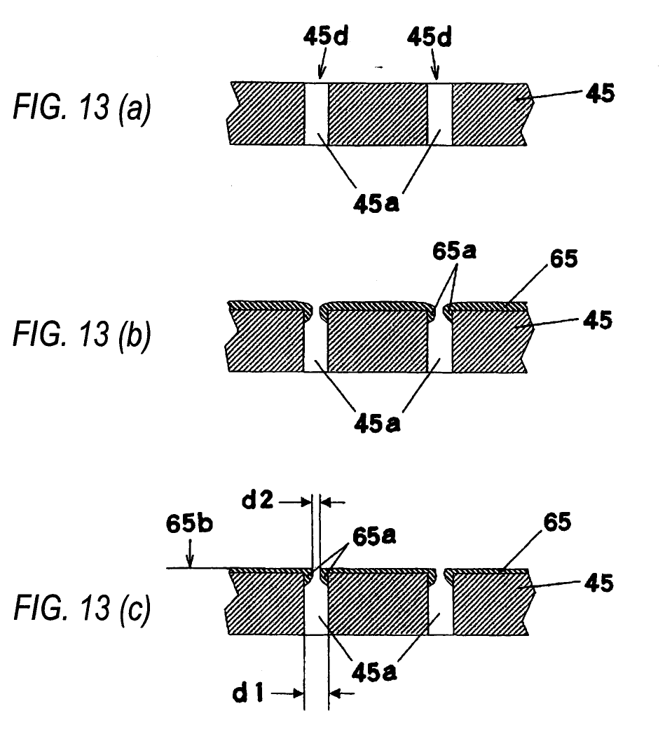

With reference to FIGS. 6, 7 and 8, description will be given to the details of the internal surface of the lower electrode 3. First of all, description will be given to the electrode member 46 having the function of suction and holding the lower surface of the semiconductor wafer 5 to be a processing object in abutment in the lower electrode 3. As shown in FIG. 6, the electrode member 46 is formed by bonding the suction member 45 to the upper surface of the cooling plate 44 through soldering. The suction member 45 is a plate-shaped member fabricated by processing a conductor such as aluminum to be almost disc-shaped, and has an upper surface on which a plurality of through holes 45a is formed. These through holes 45a are provided in communication with a central space 45b and an outer peripheral space 45c which are formed on a lower surface side of the suction member 45. A dielectric film on which alumina to be a dielectric is sprayed is formed on the upper surface of the suction member 45 as will be described below, and the dielectric film takes such a shape that the through hole 45a covers an edge of a hole portion 45d (see FIG. 13) opened on the upper surface of the suction member 45.

The central space 45b and the outer peripheral space 45c are provided corresponding to two types of semiconductor wafers 5 to be plasma treating objects, that is, a small-sized semiconductor wafer 5A and a large-sized semiconductor wafer 5B, respectively. In a state in which the semiconductor wafer 5A is mounted on the electrode member 46, a range covered with the semiconductor wafer 5A is a central area A1 and the central space 45b is provided circularly in a diameter corresponding to the central area A1. In a state in which the semiconductor wafer 5B is mounted, moreover, an outer peripheral area A2 positioned on an outer peripheral part of the central area A1 is covered with the semiconductor wafer 5B together with the central area A1. The outer peripheral space 45c is provided like a circular ring in a diameter corresponding to the outer peripheral area A2.

In a state in which the suction member 45 and the cooling plate 44 are bonded and integrated with each other, the central space 45b communicates with a central through hole 44b provided in a central part of the cooling plate 44 and the outer peripheral space 45c communicates with a side through hole 44c provided on an outer edge part of the cooling plate 44. Moreover, a circular ring-shaped cooling hole 44a for circulating cooling water is formed on a lower surface of the cooling plate 44.

In a state in which the electrode member 46 is attached to the electrode attaching portion 42, the central space 45b communicates with the joint member 28 through a ventilation tube 49A inserted to vertically penetrate through an inside of the central through hole 44b and the shaft portion 42a as shown in FIG. 2. The outer peripheral space 45c communicates with the joint member 27 through the side through hole 44c, and furthermore, through a ventilation tube 49B inserted through a dielectric 48 penetrating through the dielectric 41 and the bottom portion 40c. Moreover, the cooling hole 44a communicates with the joint members 30 and 31 through refrigerant passages 42b and 42c provided in the shaft portion 42a.

The two-system sucking and blow lines VB1 and VB2 shown in FIG. 1 are connected to the joint members 27 and 28 respectively, and can carry out a vacuum suction in an optional timing from each through hole 45a in the central area A1 and the outer peripheral area A2 shown in FIG. 6 and can blow positive pressure air. Consequently, the semiconductor wafers 5A and 5B having different diameters can be sucked and held by the common electrode member 46, and furthermore, the hold can be released.

More specifically, in the case in which the semiconductor wafer 5A is an object, only the central space 45b is sucked to hold the semiconductor wafer 5A onto the suction member 45. In the case in which the suction of the semiconductor wafer 5A is released, the positive pressure air is supplied into the central space 45b to blow the air from the through hole 45a, thereby peeling the semiconductor wafer 5A from the upper surface of the suction member 45.

In the case in which the semiconductor wafer 5B is the object, moreover, both the central space 45b and the outer peripheral space 45c are sucked to hold the semiconductor wafer 5B onto the suction member 45. In the case in which the suction of the semiconductor wafer 5B is released, the positive pressure air is first supplied into the central space 45b and is then supplied into the outer peripheral space 45c with a time difference. Consequently, it is possible to peel the semiconductor wafer 5B from a central part of a wafer earlier. Also in the case in which the semiconductor wafer 5B having a large size is the object, it is possible to smoothly peel the wafer in a short time in a small amount of an air blow.

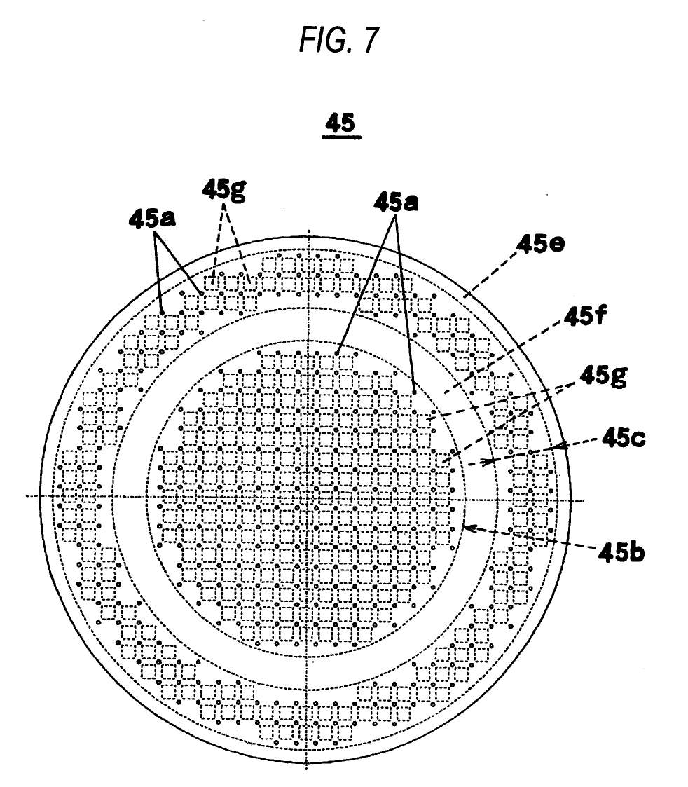

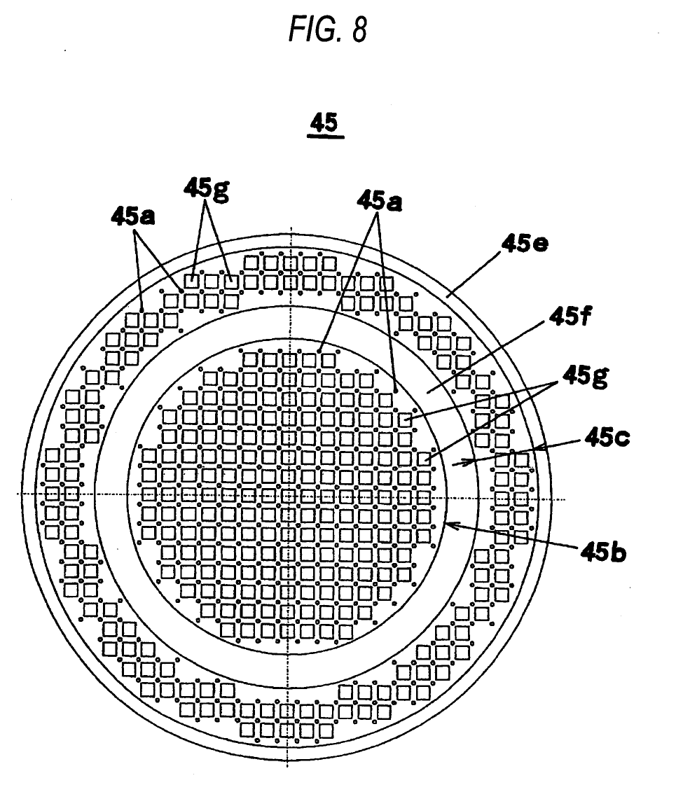

With reference to FIGS. 7 and 8, next, description will be given to the detailed shape of the suction member 45 to be used in the electrode member 46. FIGS. 7 and 8 show upper and lower surfaces of the suction member 45, respectively. In FIGS. 7 and 8, the circular central space 45b and the circular ring-shaped outer peripheral space 45c positioned on an outer periphery of the central space 45b are formed on the lower surface of the suction member 45 taking the shape of a disc by cutting the suction member 45 in a predetermined depth, respectively. An outer edge of the outer peripheral space 45c is isolated from the outer peripheral surface through a first ring-shaped bonding surface 45e, and the central space 45b and the outer peripheral space 45c are isolated from each other through a second ring-shaped bonding surface 45f.

The through holes 45a are formed in a lattice array in the central space 45b and the outer peripheral space 45c, and furthermore, island-shaped bonding surfaces 45g taking a square shape are similarly provided in the lattice array in a position surrounded by four of these through holes 45a which are adjacent to each other. A bottom face of the island-shaped bonding surface 45g is on the level with the first ring-shaped bonding surface 45e and the second ring-shaped bonding surface 45f. When the suction member 45 is to be bonded to the cooling plate 44 by soldering, the first ring-shaped bonding surface 45e, the second ring-shaped bonding surface 45f and the island-shaped bonding surface 45g are soldered onto bonding surfaces corresponding to these bonding surfaces over the upper surface of the cooling plate 44.

In the structure in which the suction member 45 and the cooling plate 44 are bonded by soldering to form the integral electrode member 46, thus, the island-shaped bonding surface 45g is disposed as uniformly and densely as possible within the range of the central space 45b and the outer peripheral space 45c in addition to the first ring-shaped bonding surface 45e and the second ring-shaped bonding surface 45f so that a great bonding strength can be maintained and the heat in the plasma treatment can be efficiently transmitted from the suction member 45 to the cooling plate 44. In the case in which the bonding surface is formed on the lower surface of the suction member 45, a bonding surface for coupling the first ring-shaped bonding surface 45e and the second ring-shaped bonding surface 45f may be added in such a configuration as to cross the outer peripheral space 45c in a radial direction.

Next, description will be given to the upper electrode 4 and the up-down mechanism for moving the upper electrode 4. As shown in FIG. 2, the upper electrode 4 has a holding member 50 obtained by processing a conductor such as aluminum to take such a shape that a shaft portion 50a is extended upward. The almost disc-shaped intermediate plate 51 formed of a conductor in the same manner is fixed to the lower surface of the holding member 50, and furthermore, a shower plate 52 having an outer periphery held through a holding ring 53 is attached to the lower surface of the intermediate plate 51.

The outer edge portion 51a to abut on the sealing surface 40d is provided in the intermediate plate 51 so as to be extended in the direction of the outside diameter. The shower plate 52 and the holding ring 53 which are positioned on the inside of the outer edge portion 51a take such shapes that they are protruded downward from the lower surface of the outer edge portion 51a by a protrusion dimension D2, and the lower surfaces of the shower plate 52 and the holding ring 53 are protruded surfaces which are protruded downward from the lower surface of the outer edge portion 51a.

The shaft portion 50a is held to be vertically movable by means of a bearing portion 54 provided on the upper plate 6, and furthermore, is coupled to the up-down driving portion 7 disposed on the upper plate 6 through a coupling member 55. The upper plate 6 and the bearing portion 54 constitute a support mechanism for holding the upper electrode 4 to be upward and downward movable. When the up-down driving portion 7 is driven, the upper electrode 4 is moved upward and downward and the outer edge portion 51a provided in the intermediate plate 51 abuts on the sealing surface 40d provided in the chamber container 40 in a downward moving position. Consequently, the processing space 2a having a height H2 is formed between the electrode member 46 of the lower electrode 3 and the shower plate 52 of the upper electrode 4.

At this time, the portion provided above the upper electrode 4 in the vacuum chamber 2 is the ordinary pressure apace 2b which always has an equal pressure to an outside air pressure. Also in the case in which a high frequency voltage is applied between the upper electrode 4 and the lower electrode 3 in order to generate a plasma in the processing space 2a, accordingly, an abnormal discharge is not generated above the upper electrode 4. Consequently, it is possible to prevent a consumed power loss and a variation in a plasma discharge from being caused by the abnormal discharge while maintaining a necessary up-down margin for constituting the upper electrode 4 to be upward and downward movable. Thus, it is possible to efficiently carry out a stable plasma treatment.

In the upper electrode 4, the height from the lower surface of the outer edge portion 51a to that of the holding ring 53, that is, the protrusion dimension D2 in which the protruded surface is protruded downward from the lower surface of the outer edge portion 51a is set to be greater than the height D1 from the upper end of the delivery port 40f to the sealing surface 40d positioned just above the delivery port 40f. In a state in which the upper electrode 4 is moved downward, accordingly, the lower surface of the holding ring 53 is positioned below the upper end of the delivery port 40f Consequently, the height H2 between the shower plate 52 and the suction member 45 in the processing space 2a, that is, the clearance between the electrodes can be set to be a small clearance which is suitable for efficiently carrying out the plasma treatment using a fluoric gas in which the semiconductor wafer 5 is the object.

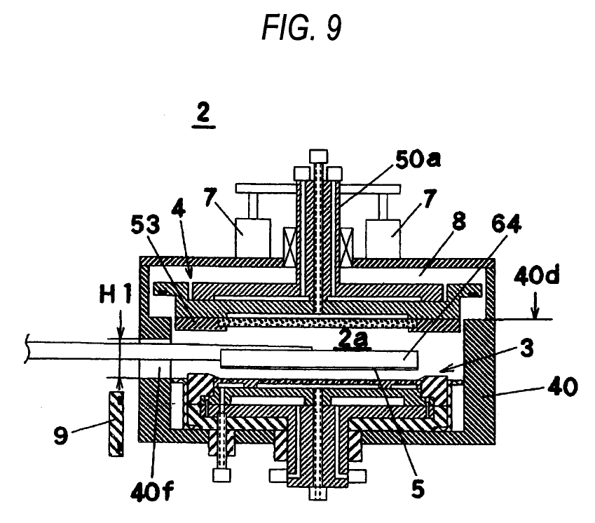

In a state in which the up-down driving portion 7 is driven to move the upper electrode 4 upward as shown in FIG. 9, the holding ring 53 is positioned above the delivery port 40f. When the door 9 is opened in this state, the delivery port 40f is brought into an open state. At this time, the upper electrode 4 is not present within the range of the opening height H1 of the delivery port 40f. In a work delivering operation for delivering the semiconductor wafer 5 in and out of the processing space 2a by means of a substrate delivering mechanism 64, accordingly, an interference of the substrate delivering mechanism 64 and the upper electrode 4 is not caused.

More specifically, in the plasma treating apparatus according to the embodiment, the protrusion dimension D2 in the upper electrode 4 is set to be greater than the height D1 in the chamber container 40. Consequently, it is possible to maintain the opening height H1 which is required for carrying out the delivering operation without a hindrance while implementing the small clearance between the electrodes which is desirable for carrying out, at a high efficiency, the plasma treatment in which the semiconductor wafer 5 is the object.

In the structure, the upper electrode 4 has such a configuration as to include the ring-shaped outer edge portion 51a which can abut on the sealing surface 40d and to have a protruded surface which is protruded downward from a lower surface of the outer edge portion 51a on a lower surface side at an inside of the outer edge portion 51a. The up-down driving portion 7 serves as an up-down mechanism for causing the outer edge portion 51a to abut on the sealing surface 40d, thereby forming the processing space 2a sealed between the lower electrode 3 and the upper electrode 4. The up-down mechanism has such a structure as to be attached to a support mechanism for holding the upper electrode 4 to be upward and downward movable. By employing such a structure, the structure of the vacuum chamber 2 can be simplified and compact.

In FIG. 2, a gas space 51c is formed on a lower surface of the intermediate plate 51 corresponding to an upper surface side of the shower plate 52. The gas space 51c communicates with the joint member 16 through a ventilation tube 49C penetrating through an inside of the shaft portion 50a. The joint member 16 is connected to the opening/closing valve 15 shown in FIG. 1. After a process gas fed from the process gas supply portion 13 reaches the gas space 51c, it is blown out of minute holes of the shower plate 52 into the processing space 2a.

A cooling jacket 50d for circulating a refrigerant is formed on the lower surface side of the holding member 50. The cooling jacket 50d communicates with the joint members 32 and 33 through refrigerant passages 50b and 50c provided in the shaft portion 50a. The joint members 32 and 33 are connected to the cooling unit 29 shown in FIG. 1. The cooling unit 29 is driven to circulate the refrigerant into the cooling jacket 50d, thereby cooling the intermediate plate 51 having a temperature raised by the plasma treatment to prevent an overheat.

Next, description will be given to the opening/closing mechanism for opening and closing the upper plate 6 together with the upper electrode 4. In FIGS. 2 and 3, two opening/closing members 57 are fixed, through coupling blocks 57a, to the upper surface of the upper plate 6 in an abutment state on the upper end face E of the sidewall upper portion 40b, and a holding rod 56 is coupled to an end on one side (a right side in FIG. 3) of each of the two opening/closing members 57 in a form for connecting them. A hinge block 58 is fixed to a left side surface of the chamber container 40, and a horizontal hinge shaft 59 is pivotally supported on the hinge block 58.

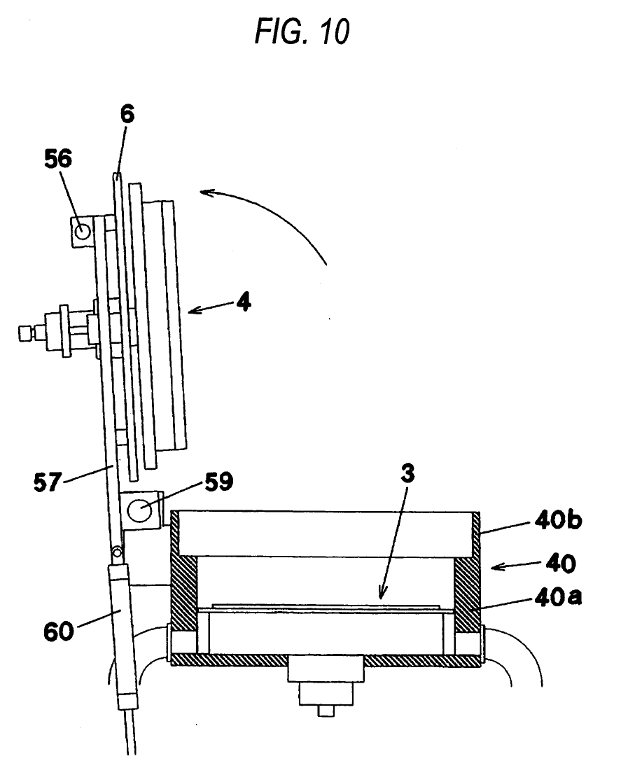

The other side of the opening/closing member 57 is extended to the outside of the upper plate 6 and is pivotally supported through the hinge shaft 59. Furthermore, a damper 60 is coupled to an end of the opening/closing member 57 through a pin 60a. The opening/closing member 57, the hinge block 58 and the hinge shaft 59 constitute a hinge mechanism for rotating the upper plate 6 to carry out opening/closing operations. When the upper plate 6 is to be opened, the holding rod 56 is held and lifted upward to rotate the upper plate 6 together with the upper electrode 4 around the hinge shaft 59 as shown in FIG. 10.

Consequently, the chamber container 40 is brought into such a state that an opening portion on an upper surface is wholly opened. Thus, it is possible to carry out a maintenance work such as the exchange of the electrode member in the lower electrode 3 or cleaning in an inner part with a high workability. More specifically, in the embodiment, a support mechanism for holding the upper electrode 4 has such a structure as to be attached rotatably around a horizontal axis by means of the hinge mechanism. The damper 60 has the function of relieving a holding force required for supporting the dead weights of the upper electrode 4 and the upper plate 6 when closing the opened upper plate 6, thereby carrying out an opening/closing working operation easily.

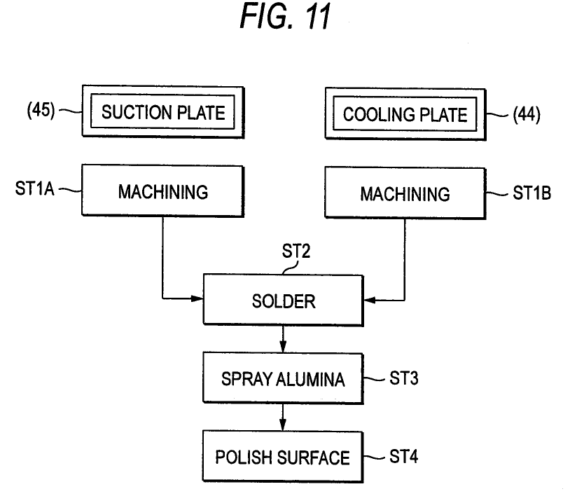

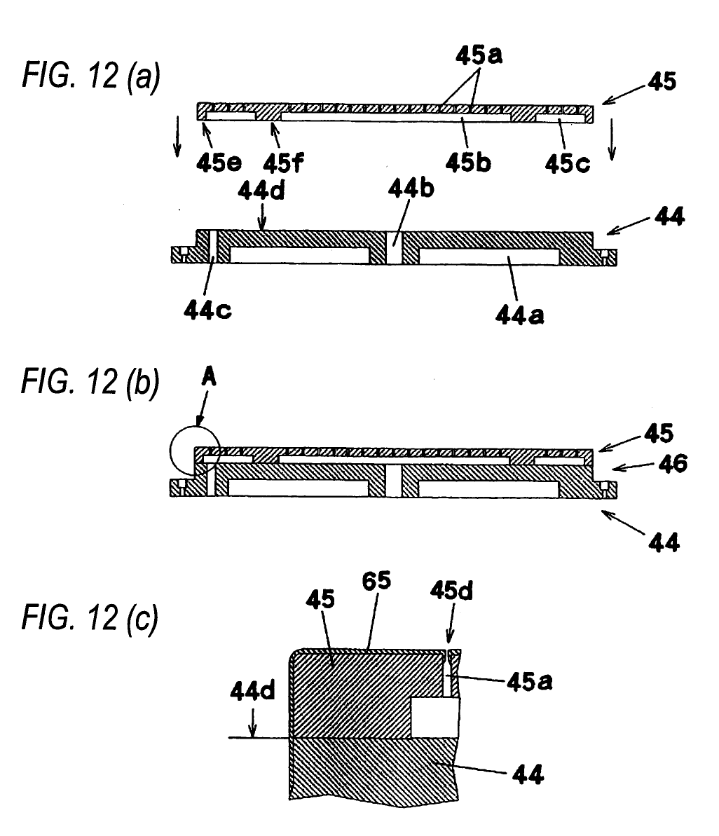

With reference to FIGS. 11, 12 and 13, next, description will be given to a method of manufacturing the electrode member 46 to be used in the lower electrode 3. Herein, there is shown a process for integrating the suction member 45 and the cooling plate 44 which constitute the electrode member 46, thereby manufacturing the electrode member 46 to be attached to the lower electrode 3. First of all, the cooling plate 44 and the suction member 45 which are individual components are fabricated by machining, respectively (ST1A) and (ST1B). More specifically, as shown in FIG. 12(a), the through hole 45a, the central space 45b, the outer peripheral space 45c, the first ring-shaped bonding surface 45e and the second ring-shaped bonding surface 45f are formed on a disc-shaped member to fabricate the suction member 45, and similarly, the cooling jacket 44a, the central through hole 44b, the side through hole 44c and a soldered surface 44d are formed by machining to fabricate the cooling plate 44. The machining is carried out in such a manner that a planar shape of the lower surface of the suction member 45 is identical to that of the soldered surface 44d of the cooling plate 44.

Subsequently, a soldering operation is carried out (ST2). More specifically, as shown in FIGS. 12(a) and (b), the first ring-shaped bonding surface 45e and the second ring-shaped bonding surface 45f are bonded to the soldered surface 44d by soldering so that the cooling plate 44 and the suction member 45 are integrated with each other. Then, alumina spraying is carried out (ST3). More specifically, alumina to be a dielectric is sprayed to form a dielectric film by setting the upper surface of the suction member 45 integrated with the cooling plate 44 as an object. In other words, as shown in FIG. 13(b), an alumina sprayed film 65 is formed on the upper surface of the suction member 45 set in a state shown in FIG. 13(a).

In this case, in the hole portion 45d in which the through hole 45a is opened on the upper surface of the suction member 45 to be a plate-shaped member, the sprayed film 65 is partially suspended and stuck into the through hole 45a so that the molten alumina becomes a hole portion sticking dielectric film 65a taking such a shape as to be stuck to the edge of the hole portion 45d to be covered. Moreover, the spray range of the alumina is not restricted to only the upper surface of the suction member 45 but the sprayed film 65 is formed within a range including a full range of the side end face of the suction member 45 and a part of a side end face of the cooling plate 44 (a lower range from the soldered surface 44d by a predetermined width) as shown in FIG. 13(c) in a state in which the lower surface of the suction member 45 is bonded to the soldered surface 44d taking an identical planar shape.

Thereafter, surface polishing is carried out by setting the alumina sprayed surface to be an object (ST4). More specifically, as shown in FIG. 13(c), the sprayed film 65 which is sprayed onto the upper surface of the suction member 45 is mechanically polished to form a smooth covered surface 65b. By the mechanical polishing, the upper surface of the hole portion sticking dielectric film 65a covering the hole portion 45d of the through hole 45a is removed partially. An effective hole diameter of an opening portion of the through hole 45a processed in a hole diameter d1 at the beginning is set to be d2 which is smaller than d1. Accordingly, it is possible to form the through hole 45a in the larger hole diameter d1 than the hole diameter d2 which is required for properly carrying out a vacuum suction and an air blow. Consequently, it is possible to provide a through hole having a very small diameter without requiring a processing of forming a minute hole having a high degree of processing difficulty.

More specifically, the electrode member manufacturing method of manufacturing the electrode member 46 has such a configuration as to include a through hole forming step of forming a plurality of through holes 45a on the suction member 45, a spraying step of spraying alumina onto the upper surface of the suction member 45 having the through holes 45 formed thereon, thereby forming the sprayed film 65 taking such a shape as to cover the edge of the hole portion 45d in which the through holes 45a are formed on the upper surface of the suction member 45, and a surface polishing step of mechanically polishing the surface of the suction member 45 on which the sprayed film 65 is formed.

By covering a portion to be exposed to the upper surface in the lower electrode 3 and subjected to a plasma with the dielectric film having the configuration described above, thus, it is possible to obtain the following excellent advantages. In the conventional apparatus, most of the surface of the electrode member has a structure in which a metallic surface is exposed. For this reason, every time cleaning for removing a deposited substance which is stuck into the vacuum chamber is executed by plasma ashing, the metal portion of the electrode member is exposed to the plasma. Therefore, the surface of the electrode member is removed by the sputtering effect of the plasma and the lifetime of the component of the electrode member is shortened, resulting in an increase in a component consuming cost, and furthermore, a scattered substance generated by sputtering is stuck to contaminate the internal surface of the apparatus.

On the other hand, in the embodiment, there is employed the structure in which the upper surface of the electrode member 46 is covered with the dielectric film. Therefore, the metallic surface is not directly exposed to the plasma. Accordingly, it is possible to suppress the generation of a scattered substance due to the removal of a metal by the sputtering, thereby preventing the contamination of the inner part of the apparatus due to the sticking of the scattered substance and prolonging a lifetime of the component of the electrode member in the lower electrode.

In the embodiment, furthermore, the hole portion sticking dielectric film 65a taking such a shape as to cover the edge of the hole portion 45d is formed. Consequently, it is possible to enhance an etching resistance in the edge part of the opening portion of the through hole 45a, thereby prolonging the local lifetime of the component and preventing an abnormal discharge which is apt to be generated in the edge portion. By covering the side end face of the suction member 45 and a part of the side end face of the cooling plate 44 with the sprayed film 65 over the outer peripheral surface of the electrode member 46, moreover, it is possible to prevent the generation of the abnormal discharge in the vicinity of the outer periphery of the lower electrode 3.

In a process for attaching the electrode member 46 to the lower electrode 3 to repetitively execute the plasma treatment setting the semiconductor wafer 5 to be an object, the surface of the suction member 45 is damaged by the etching action of the plasma so that the covered surface 65b becomes rough. When the surface damage is progressed, the electrode member 46 is brought into a state in which it cannot be used and is therefore exchanged for a new electrode member 46. While the electrode member 46 having the surface damage has conventionally been discharged as a consumed component exceeding a durable lifetime, the electrode member 46 according to the embodiment can be reused by carrying out a regenerating process through the following recycling method.

In the recycling method, first of all, the sprayed film 65 provided on the upper surface of the suction member 45 is removed by a method such as a blast in the spent electrode member 46 (a film removing step). Subsequently, the sprayed film 65 is formed by spraying again, in the same manner as in FIG. 13(b), over the upper surface of the suction member 45 from which the sprayed film 65 has been removed (a respraying step). Then, the surface of the suction member 45 obtained after the spraying is mechanically polished again. Consequently, the smooth covered surface 65b is formed on the sprayed film 65 provided on the upper surface of the suction member 45 as shown in FIG. 12(c) and a usable state can be thus brought again. Therefore, it is possible to repetitively use an electrode member having a high cost which is fabricated through complicated machining and bonding steps. Thus, it is possible to reduce a running cost of the plasma treating apparatus.

This application is based upon and claims the benefit of priority of Japanese Patent Application No. 0.2005-263410 filed on Sep. 12, 2005, the contents of which are incorporated herein by reference in its entirety.

### INDUSTRIAL APPLICABILITY

A plasma treating apparatus, an electrode member for the plasma treating apparatus, a method of manufacturing the electrode member and a recycling method according to the invention have an advantage that a lifetime of an electrode member constituting a lower electrode can be prolonged to reduce a component consuming cost and an inner part of the apparatus can be prevented from being contaminated by a scattered substance, and they are useful for the field of a plasma treatment in which a plate-shaped work such as a semiconductor wafer is set to be an object.

1. A plasma treating apparatus for carrying out a plasma treatment by setting a plate-shaped work to be an object, comprising:
a vacuum chamber;
a lower electrode provided in the vacuum chamber and having the work mounted thereon;
an upper electrode disposed above the lower electrode;
a processing space formed between the lower electrode and the upper electrode; and
plasma generating means for generating a plasma in the processing space,
wherein an electrode member to abut on a lower surface of the work in the lower electrode includes
a plate-shaped member on which a plurality of through holes is formed, and
a dielectric film formed by spraying a dielectric onto an upper surface of the plate-shaped member and taking such a shape as to cover an edge of a hole portion in which the through holes are formed on the upper surface of the plate-shaped member.

2. An electrode member for a plasma treating apparatus for carrying out a plasma treatment by setting a plate-shaped work to be an object which is used in the plasma treating apparatus and abuts on a lower surface of the work in a lower electrode having the work mounted thereon, the electrode member comprising:
a plate-shaped member on which a plurality of through holes is formed, and
a dielectric film formed by spraying a dielectric onto an upper surface of the plate-shaped member and taking such a shape as to cover an edge of a hole portion in which the through holes are formed on the upper surface of the plate-shaped member.

3. An electrode member manufacturing method of manufacturing an electrode member for a plasma treating apparatus for carrying out a plasma treatment by setting a plate-shaped work to be an object which is used in the plasma treating apparatus and abuts on a lower surface of the work in a lower electrode having the work mounted thereon, comprising:
a through hole forming step of forming a plurality of through holes on a plate-shaped member;
a spraying step of spraying a dielectric onto an upper surface of the plate-shaped member having the through holes formed thereon, thereby forming a dielectric film taking such a shape as to cover an edge of a hole portion in which the through holes are formed on the upper surface of the plate-shaped member; and
a surface polishing step of mechanically polishing a surface of the plate-shaped member having the dielectric film formed thereon.

4. The electrode member manufacturing method according to claim 3, wherein a cooling member taking an identical planar shape to a shape of the plate-shaped member is bonded to a lower surface of the plate-shaped member, and the dielectric is sprayed to cover a side end face of the plate-shaped member and a part of a side end face of the cooling member at the spraying step.

5. An electrode member recycling method of reusing an electrode member which is used in a plasma treating apparatus for carrying out a plasma treatment by setting a plate-shaped work to be an object and is manufactured by a manufacturing method, comprising a through hole forming step of forming a plurality of through holes on a plate-shaped member, a spraying step of spraying a dielectric onto an upper surface of the plate-shaped member having the through holes formed thereon, thereby forming a dielectric film taking such a shape as to cover an edge of a hole portion in which the through holes are formed on the upper surface of the plate-shaped member, and a surface polishing step of mechanically polishing a surface of the plate-shaped member having the dielectric film formed thereon, the recycling method comprising:
a film removing step of removing the sprayed film of the spent electrode member, and
a respraying step of spraying a dielectric onto the upper surface of the plate-shaped member obtained after removing the sprayed film, thereby forming the dielectric film again.
